(19) United States
(12) Patent Application Publication
(10) Pub. No.: US 2012/0073644 A1
(43) Pub. Date: Mar. 29, 2012

(54) Photovoltaic Device

(76) Inventor: Seung-Yeop Myong, Seoul (KR)

(21) Appl. No.: 13/308,242

(22) Filed: Nov. 30, 2011

Related U.S. Application Data
(63) Continuation-in-part of application No. 12/762,798, filed on Apr. 19, 2010.

(30) Foreign Application Priority Data
Jun. 12, 2009 (KR) 10-2009-0052236

(51) Int. Cl. H01L 31/0224

(52) U.S. Cl. 136/256

(57) ABSTRACT

Disclosed is a photovoltaic device that includes: a substrate; a first electrode disposed on the substrate; a photoelectric transformation layer disposed on the first electrode, the photoelectric transformation layer comprising a light absorbing layer which comprises at least one pair of an intrinsic first sub-layer and an intrinsic second sub-layer, each of which comprises hydrogenated amorphous silicon based material and hydrogenated proto-crystalline silicon based material having a crystalline silicon grain; and a second electrode disposed on the photoelectric transformation layer.

### CROSS-REFERENCE TO RELATED APPLICATIONS

This application is a continuation-in-part application of U.S. patent application Ser. No. 12/762,798 filed on Apr. 15, 2010, which claims the benefit of Korean Patent Application No. 10-2009-0052236 filed on Jun. 12, 2009, the entireties of which are hereby incorporated by reference.

### FIELD OF THE INVENTION

This application relates to a photovoltaic device.

### BACKGROUND OF THE INVENTION

Recently, as existing energy sources such as oil and charcoal and so on are expected to be exhausted, attention is now paid to alternative energy sources which can be used in place of the existing energy sources. Among the alternative energy sources, sunlight energy is abundant and has no environmental pollution. For this reason, more and more attention is paid to the sunlight energy.

A photovoltaic device, that is to say, a solar cell converts directly sunlight energy into electrical energy. The photovoltaic device uses mainly photovoltaic effect of semiconductor junction. In other words, when light is incident and absorbed to a semiconductor pin junction formed through a doping process by means of p-type and n-type impurities respectively, light energy generates electrons and holes at the inside of the semiconductor. Then, the electrons and the holes are separated by an internal field so that a photo-electro motive force is generated at both ends of the pin junction. Here, if electrodes are formed at the both ends of junction and connected with wires, an electric current flows externally through the electrodes and the wires.

In order that the existing energy sources such as oil is substituted with the sunlight energy source, it is required that a degradation rate of the photovoltaic device should be low and a stability efficiency of the photovoltaic device should be high, which are produced by the elapse of time.

### SUMMARY OF THE INVENTION

One aspect of this invention includes a photovoltaic device. The photovoltaic device includes: a substrate; a first electrode disposed on the substrate; a photoelectric transformation layer disposed on the first electrode, the photoelectric transformation layer comprising a light absorbing layer which comprises at least one pair of an intrinsic first sub-layer and an intrinsic second sub-layer, each of which comprises hydrogenated amorphous silicon based material and hydrogenated proto-crystalline silicon based material having a crystalline silicon grain; and a second electrode disposed on the photoelectric transformation layer.

### BRIEF DESCRIPTION OF THE DRAWINGS

The embodiment will be described in detail with reference to the following drawings.

FIG. 1 shows a photovoltaic device according to a first embodiment of the present invention.

FIG. 2 shows another photovoltaic device according to a second embodiment of the present invention.

FIGS. 3A to 3H show a manufacturing method of a photovoltaic device according to an embodiment of the present invention.

FIG. 4 shows a plasma-enhanced chemical vapor deposition apparatus for forming a light absorbing layer according to an embodiment of the present invention.

FIG. 5 shows variations of frequencies of a first electric power source and a second electric power source which are supplied to a chamber in order to form a light absorbing layer in accordance with an embodiment of the present invention.

FIG. 6 shows a light absorbing layer including a plurality of sub-layers included in an embodiment of the present invention.

FIG. 7 shows a light absorbing layer consisting of a hydrogenated proto-crystalline silicon single layer.

FIG. 8 shows other variations of frequencies of a first electric power source and a second electric power source which are supplied to a chamber in order to form a light absorbing layer in accordance with an embodiment of the present invention.

### DETAILED DESCRIPTION OF THE INVENTION

Embodiments will be described in a more detailed manner with reference to the drawings.

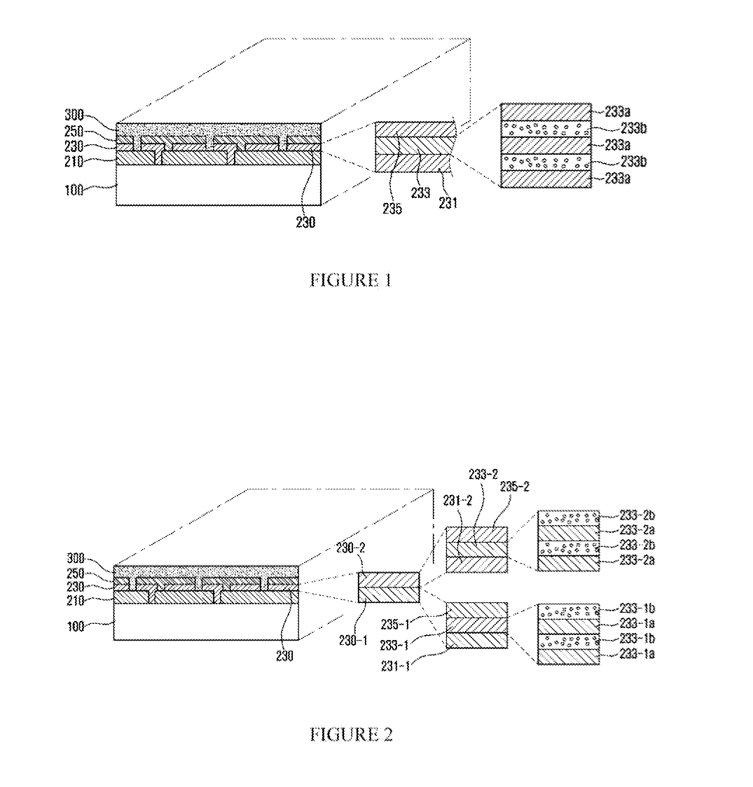

FIG. 1 shows a photovoltaic device according to a first embodiment of the present invention.

As shown, a photovoltaic device includes a substrate 100, a first electrode 210, a second electrode 250, a photoelectric transformation layer 230 and a protecting layer 300.

In detail, the first electrodes 210 are disposed on the substrate 100. The first electrodes 210 are spaced from each other at a regular interval in such a manner that adjacent first electrodes are not electrically short-circuited. The photoelectric transformation layer 230 is disposed on the first electrode 210 in such a manner as to cover the area spaced between the first electrodes at a regular interval. The second electrodes 250 are disposed on the photoelectric transformation layer 230 and spaced from each other at a regular interval in such a manner that adjacent second electrodes are not electrically short-circuited. In this case, the second electrode 250 penetrates the photoelectric transformation layer 230 and is electrically connected to the first electrode 210 such that the second electrode 250 is connected in series to the first electrode 210. The adjacent photoelectric transformation layers 230 are spaced at the same interval as the interval between the second electrodes. The protecting layer 300 is disposed on the second electrode in such a manner as to cover the area spaced between the second electrodes and the area spaced between the photoelectric transformation layers.

The photoelectric transformation layer 230 includes a p-type semiconductor layer 231, a light absorbing layer 233 and an n-type semiconductor layer 235. The light absorbing layer 233 includes at least one pair of an intrinsic first sub-layer 233A and an intrinsic second sub-layer 233B. The first sub-layer 233A includes a hydrogenated amorphous silicon based material and the second sub-layer 233B includes a hydrogenated proto-crystalline silicon based material.

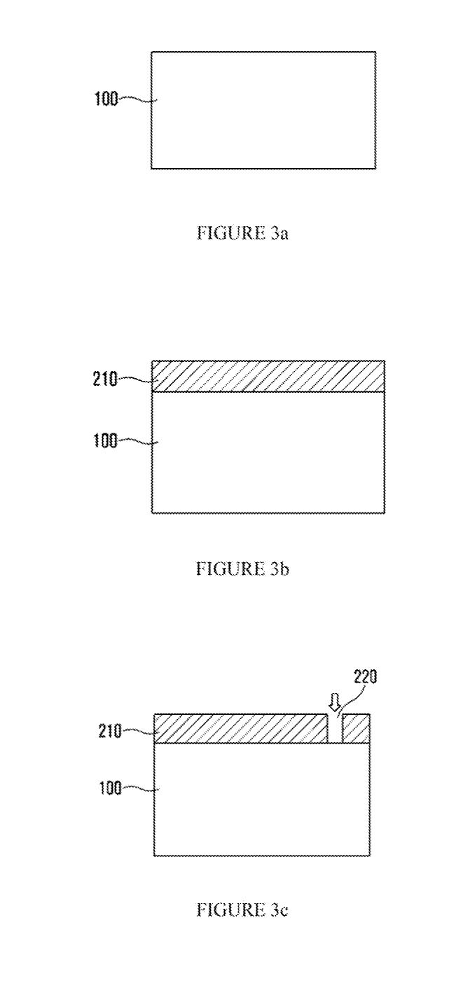

FIG. 2 shows another photovoltaic device according to a second embodiment of the present invention.

Since a photovoltaic device of FIG. 2 is almost similar to that of FIG. 1, descriptions of the same structure will be omitted. In FIG. 2, the photoelectric transformation layer 230 includes a first photoelectric transformation layer 230-1 and a second photoelectric transformation layer 230-2 disposed on the first photoelectric transformation layer. The first photoelectric transformation layer and the second photoelectric transformation layer include a p-type semiconductor layer 231-1 and 231-2, light absorbing layer 233-1 and 233-2 and n-type semiconductor layer 235-1 and 235-2.

The light absorbing layer 233-1 and 233-2 may include first sub-layer 233-1A and 233-2A and second sub-layer 233-1B and 233-2B stacked on the first sub-layer. Here, the light absorbing layer 233-1 included in the first photoelectric transformation layer 230-1 includes an intrinsic first sub-layer 233-1A and intrinsic second sub-layer 233-1B. The first sub-layer 233-1A includes a hydrogenated amorphous silicon based material and the second sub-layer 233-1B includes a hydrogenated proto-crystalline silicon based material. The light absorbing layer 233-2 included in the second photoelectric transformation layer 230-2 includes an intrinsic first sub-layer 233-2A and an intrinsic second sub-layer 233-2B. The first sub-layer 233-2A may include hydrogenated micro-crystalline silicon germanium and the second sub-layer 233-2B may include hydrogenated micro-crystalline silicon. The light absorbing layer 233-2 included in the second photoelectric transformation layer 230-2 may include a material which has a lower optical bandgap than the light absorbing layer 233-1 included in the first photoelectric transformation layer 230-1 and can absorb light of relatively longer wavelength, and thus the light usage efficiency can be maximized. The light absorbing layer 233-2 may comprise at least one material of hydrogenated amorphous silicon (a-Si:H), hydrogenated micro-crystalline silicon (μc-Si:H), hydrogenated amorphous silicon germanium (a-SiGe:H), hydrogenated proto-crystalline silicon germanium (pc-SiGe:H) and hydrogenated micro-crystalline silicon germanium (μc-SiGe:H).

While only two photoelectric transformation layers are provided in the present embodiment, three or more photoelectric transformation layers can be also provided. Regarding a second photoelectric transformation layer or a third photoelectric transformation layer among three photoelectric transformation layers, which is far from a side of incident light, the second photoelectric transformation layer or the third photoelectric transformation layer can include a light absorbing layer including an intrinsic first sub-layer and an intrinsic second sub-layer. The first sub-layer may include hydrogenated micro-crystalline silicon germanium and the second sub-layer may include hydrogenated micro-crystalline silicon. The light absorbing layer included in the second or third photoelectric transformation layer may include a material which has a lower optical bandgap than the light absorbing layer included in the first photoelectric transformation layer and can absorb light of relatively longer wavelength, and thus the light usage efficiency can be maximized. The light absorbing layer included in the second or third photoelectric transformation layer may comprise at least one material of hydrogenated amorphous silicon (a-Si:H), hydrogenated micro-crystalline silicon (μc-Si:H), hydrogenated amorphous silicon germanium (a-SiGe:H), hydrogenated proto-crystalline silicon germanium (pc-SiGe:H) and hydrogenated micro-crystalline silicon germanium (μc-SiGe:H).

With respect to such photovoltaic devices according to the first and the second embodiments, a manufacturing method of the photovoltaic device will be described below in more detail.

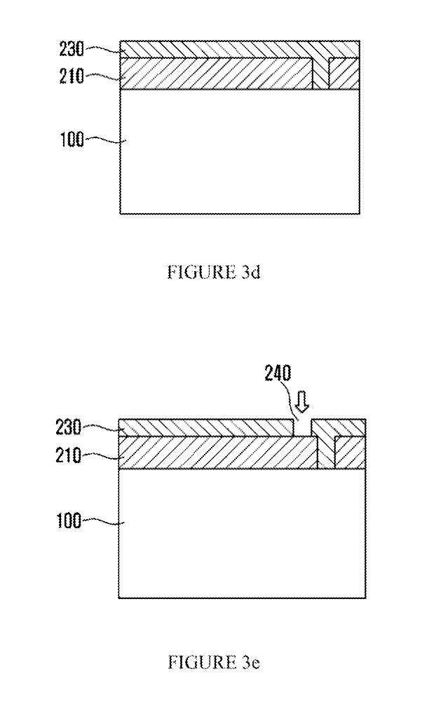

FIGS. 3A to 3H show a manufacturing method of a photovoltaic device according to an embodiment of the present invention.

As shown in FIG. 3A, a substrate 100 is provided first. An insulating transparent substrate 100 can be used as the substrate 100.

As shown in FIG. 3B, a first electrode 210 is formed on the substrate 100. In the embodiment of the present invention, the first electrode 210 can be made by chemical vapor deposition (CVD) or sputtering. The first electrode 210 can be made of transparent conductive oxide (TCO) such as SnO₂ or ZnO.

As shown in FIG. 3C, a laser beam is irradiated onto the first electrode 210 or the substrate 100 so that the first electrode 210 is partially removed. As a result, a first separation groove 220 is formed. That is, since the separation groove 210 penetrates the first electrode 210, preventing adjacent first electrodes from being short-circuited.

As shown in FIG. 3D, at least one photoelectric transformation layer 230 including a light absorbing layer is stacked by CVD in such a manner as to cover the first electrode 210 and the first separation groove 220. In this case, each photoelectric transformation layer 230 includes a p-type semiconductor layer, a light absorbing layer and an n-type semiconductor layer. In order to form the p-type semiconductor layer, source gas including silicon, for example, SiH₄ and source gas including group 3 elements, for example, B₂H₆ are mixed in a reaction chamber, and then the p-type semiconductor layer is formed by PECVD (Plasma Enhanced Chemical Vapor Deposition). Then, the source gas including silicon is flown to the reaction chamber so that the light absorbing layer is formed on the p-type semiconductor layer by PECVD. A method of manufacturing the light absorbing layer will be described later in detail. Finally, reaction gas including group 5 element, for example, PH₃ and source gas including silicon are mixed, and then the n-type semiconductor layer is stacked on an intrinsic semiconductor by PECVD. Accordingly, the p-type semiconductor layer, the light absorbing layer and the n-type semiconductor layer are stacked on the first electrode 210 in that order.

The light absorbing layer according to the embodiment of the present invention can be included in a single junction photovoltaic device including one photoelectric transformation layer 230 or in a multiple junction photovoltaic device including a plurality of photoelectric transformation layers.

As shown in FIG. 3E, a laser beam is irradiated from the air onto the substrate 100 or the photoelectric transformation layer 230 so that the photoelectric transformation layer 230 is partially removed. A second separation groove 240 is hereby formed in the photoelectric transformation layer 230.

As shown in FIG. 3F, the second electrode 250 is formed by CVD or sputtering process to cover the photoelectric transformation layer 230 and the second separation groove 240. A metal layer made of Al or Ag can be used as the second electrode 250. Also, the second electrode 250 may be made of transparent conductive oxide (TCO) such as ZnO, SnO₂ or ITO formed by CVD or sputtering.

As shown in FIG. 3G, a laser beam is irradiated from the air onto the substrate 100 so that the photoelectric transformation layer 230 and the second electrode 250 are partially removed. As a result, a third separation groove 270 is formed in the photo voltaic layer 230 and the second electrode 250.

As shown in FIG. 3H, through lamination process, a protecting layer 300 covers partially or entirely a photovoltaic cell 200 including the photoelectric transformation layer 230, the first electrode 210 and the second electrode 250 so as to protect the photovoltaic cell 200. The protecting layer 300 can include encapsulant such as ethylene Vinyl Acetate (EVA) or Poly Vinyl Butiral (PVB).

Through such a process, provided is the photoelectric transformation layer 200 having the protecting layer 300 formed thereon. A backsheet or back glass (not shown) can be made on the protecting layer.

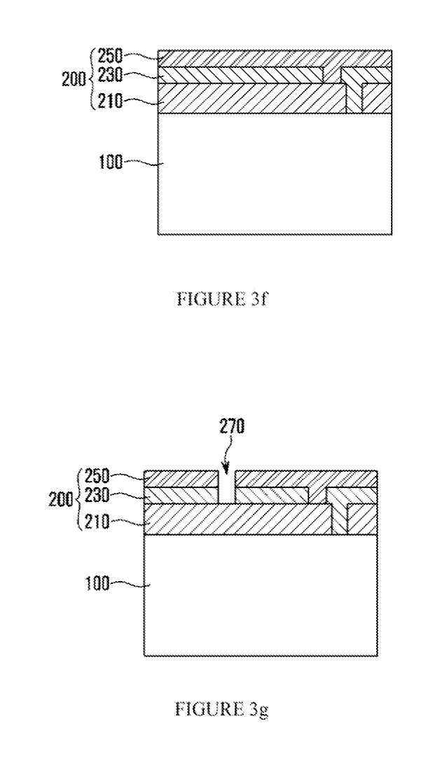

In the description below, a manufacturing method of the light absorbing layer will be described in detail with reference to FIGS. 4-8.

FIG. 4 shows a plasma-enhanced chemical vapor deposition apparatus for forming a light absorbing layer according to an embodiment of the present invention. As shown in FIG. 4, the first electrode 210 and the p-type semiconductor layer 231 are formed on the substrate 100. The substrate 100 is disposed on a plate 300 functioning as an electrode.

A vacuum pump 320 operates in order to remove impurities in a chamber 310 before the light absorbing layer forming process. As a result, the impurities in the chamber 310 are removed through an angle valve 330 so that the inside of the chamber 310 is actually in a vacuum state.

When the inside of the chamber 310 is actually in a vacuum state, source gas such as hydrogen (H₂) and silane (SiH₄) is flown to the inside of the chamber 310 through mass flow controllers MFC1 and MFC2 and an electrode 340 having a nozzle formed therein. For example, the hydrogen can be flown to the chamber through a first mass flow controller MFC1. The Silane can be flown to the chamber through a second mass flow controller MFC2. The hydrogen is flown to the chamber in order to dilute the silane and reduces Staebler-Wronski effect.

In this case, the first mass flow controller MFC1 and the second mass flow controller MFC2 are controlled to maintain the flow rates of hydrogen and silane constant. The angle valve 330 is also controlled to maintain the pressure of the chamber 310 constant.

When the source gases are flown to the chamber and a first electric power source E1 supplies a voltage having a first frequency f1 to the electrode and a second electric power source E2 supplies a voltage having a second frequency f2 to the electrode, an electric potential difference is generated between the electrode 340 and the plate 300. As a result, the source gas is in a plasma state, and the light absorbing layer is deposited on the p-type semiconductor layer 231

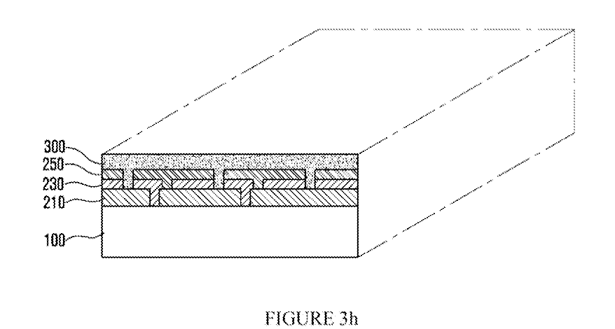

FIG. 5 shows variations of frequencies of the first electric power source E1 and a second electric power source E2 which are supplied to the chamber 310 in order to form a light absorbing layer in accordance with an embodiment of the present invention. The first electric power source E1 supplies a first voltage having the first frequency f1. The second electric power source E2 supplies a second voltage having the second frequency f2. Here, as shown in FIG. 5, the first voltage having the first frequency f1 and the second voltage having the second frequency f2 are alternately supplied to the electrode. A ratio between a time period t1 for supplying the first voltage and a time period t2 for supplying the second voltage is maintained constant.

As described above, since the flow rates of hydrogen and silane, the pressure of the chamber 310 and a ratio between the time periods for supplying voltages having mutually different frequencies are maintained constant, a hydrogen dilution ratio in the chamber 310, that is, a ratio of a flow rate of hydrogen to a flow rate of silane is also maintained constant.

As such, since the hydrogen dilution ratio is maintained constant, turbulence caused by the variations of the flow rates of hydrogen and silane is prevented from being generated in the chamber 310. Particularly, if the chamber 310 is used for manufacturing a large area photovoltaic device, there is an increasing possibility of generating the turbulence caused by the source gas. Therefore, it is easier to manufacture the large area photovoltaic device by maintaining the constant pressure of the chamber and the constant flow rates of hydrogen and silane.

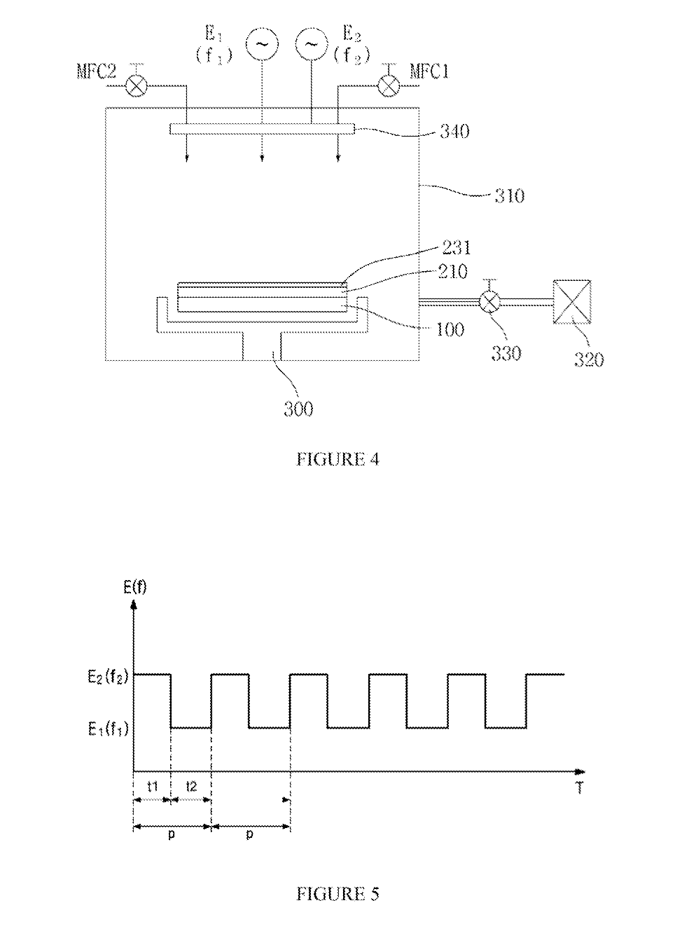

Meanwhile, as shown in FIG. 6, the light absorbing layer 233 including a plurality of the sub-layers 233A and 233B is formed on the p-type semiconductor layer 231. That is, when the first voltage having the first frequency f1 lower than the second frequency f2 is supplied to the electrode, the first sub-layer 233A which is deposited relatively slowly is formed. The first sub-layer 233A includes amorphous silicon. When the second voltage having the second frequency f2 lower than the first frequency f1 is supplied to the electrode, the second sub-layer 233B which is deposited relatively rapidly is formed. The second sub-layer 233B includes a crystalline silicon grain.

The higher the frequency is, the higher a plasma density is. Therefore, a deposition rate increases and an electron temperature decreases. As a result, ion damages on a thin film surface or an interface are reduced, making it easier to grow a crystal.

The first sub-layer 233A corresponds to a hydrogenated amorphous silicon sub-layer (a-Si:H) including amorphous silicon. The second sub-layer 233B corresponds to a hydrogenated proto-crystalline silicon sub-layer (pc-Si:H) including a crystalline silicon grain. The hydrogenated proto-crystalline silicon is produced during the process of a phase change of the amorphous silicon into micro-crystalline silicon. The hydrogenated proto-crystalline silicon has a structure in which crystalline silicon grains (3 to 10 nm in diameter) are embedded in amorphous silicon matrix. Thus, components of crystal silicon are not detected by XRD (X-Ray Diffraction) or Raman Spectroscopy on the hydrogenated proto-crystalline silicon. However, crystalline silicon grains can be detected from HRTEM (High Resolution Transmission Electron Microscopy) images of the hydrogenated proto-crystalline silicon.

As such, when the light absorbing layer 233 including a plurality of the sub-layers 233A and 233B is made, the degradation rate, i.e., a value which is obtained by dividing a difference between initial efficiency and stabilization efficiency by the initial efficiency, is reduced. Accordingly, the photovoltaic device according to the embodiment of the present invention can have high stabilization efficiency.

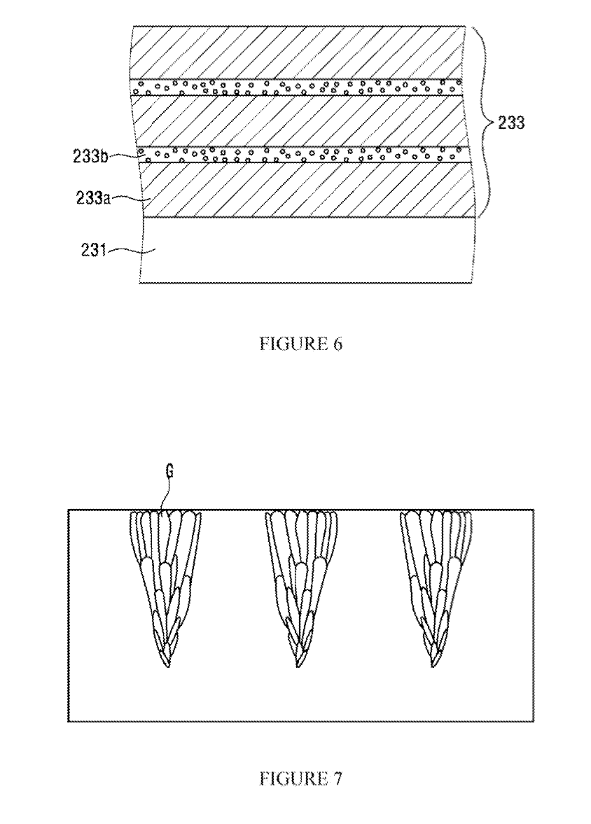

In other words, the first sub-layer 233A made of an amorphous silicon based material. interrupts columnar growth of the crystalline silicon grain of the second sub-layer 233B. As shown in FIG. 7, when the light absorbing layer is formed of only a proto-crystalline silicon layer unlike the embodiment of the present invention, the columnar growth of the crystalline silicon grain is accomplished. That is to say, as deposition is performed, the diameter of the crystalline silicon grain G is increased.

Such a columnar growth of the crystalline silicon grain increases a recombination rate of carriers such as an electron hole and an electron at a grain boundary, thus the initial efficiency of a photovoltaic device is lowered. Moreover the columnar growth of the crystalline silicon grain lowers the optical bandgap of a light absorbing layer, thus the absorption efficiency for short-wavelength. visible light and the short-circuit current are reduced.

However, in the case of the light absorbing layer 233 including a plurality of sub-layers 233A and 233B in the embodiment of the present invention, since a short-range-order (SRO) and a medium-range-order (MRO) in the silicon thin film matrix are improved, the degradation rate of the light absorbing layer 233 is lowered and the stabilization efficiency is increased.

The amorphous silicon of the first sub-layer 233A interrupts columnar growth of the crystalline silicon grain in the second sub-layer 233B and thus the second sub-layer 233B has a uniform thickness (within an allowable error range). Accordingly, a time required for the efficiency of the photovoltaic device to reach the stabilization efficiency is reduced and high stabilization efficiency is obtained. Besides, the hydrogen dilution ratio which is actually maintained constant (within an allowable error range) in the chamber 310 during a deposition time also causes the crystalline silicon grains of the second sub-layer 233B to have a uniform diameter. Accordingly, a time required for the efficiency of the photovoltaic device to reach the stabilization efficiency is reduced and high stabilization efficiency is obtained.

The crystalline silicon grains of the second sub-layer 233B are covered with amorphous silicon based material and isolated from each other. The isolated crystalline silicon grains act as radiative recombination centers of some of the captured carriers, and hence suppress photocreation of dangling bonds. As a result, the non-radiative recombination in the amorphous silicon based material, which surrounds the crystalline silicon grains of the second sub-layer 233B, is reduced.

As described above, in the embodiment of the present invention, plasma-enhanced chemical vapor deposition method is used instead of photo-CVD. The photo-CVD is not suitable for manufacturing a large area photovoltaic device. Also, as deposition is performed, a thin film is deposited on a quartz window of a photo-CVD device, reducing UV light penetrating through the quartz window.

For this reason, a deposition rate is gradually reduced and the thicknesses of the first sub-layer 233A and the second sub-layer 233B are gradually reduced. Contrarily, the plasma-enhanced chemical vapor deposition (PECVD) method can solve the shortcomings of the photo-CVD.

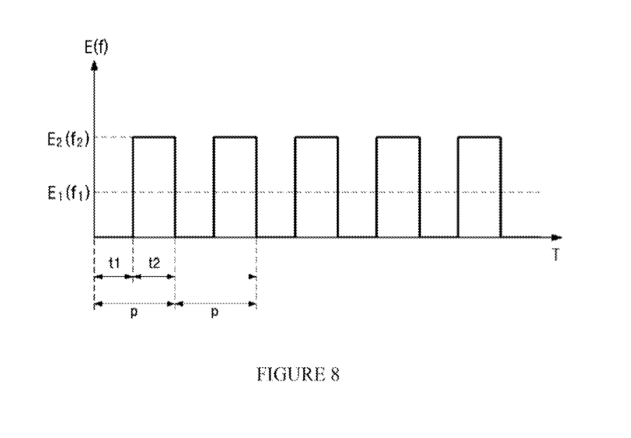

FIG. 8 shows other variations of frequencies of a first electric power source and a second electric power source which are supplied to a chamber in order to form a light absorbing layer in accordance with an embodiment of the present invention.

As shown in FIG. 8, the voltage having the first frequency f1 is continuously supplied to the electrode during the deposition time. The voltage having the second frequency f2 higher than the first frequency f1 is alternately supplied to the electrode. As a result, the deposition time includes a time period t1 for supplying the voltage having the first frequency f1 and a time period t2 for supplying the voltages having the first frequency f1 and the second frequency f2.

When the first voltage having the first frequency f1 lower than the second frequency f2 is supplied by supplying a voltage according to a frequency variation shown in FIG. 8, the first sub-layer 233A which is deposited relatively slowly is formed. The first sub-layer 233A includes amorphous silicon. When the second voltage having the second frequency f2 lower than the first frequency f1 is supplied with the first voltage to the electrode, the second sub-layer 233B which is deposited relatively rapidly is formed. The second sub-layer 233B includes a crystalline silicon grain.

As such, since the light absorbing layer 233 including the first and the second sub-layers 233A and 233B is made, the degradation rate is reduced. Accordingly, the photovoltaic device according to the embodiment of the present invention can have high stabilization efficiency.

When a voltage is supplied according to a frequency variation shown in FIG. 5, it is required that a starting point of time for the supply of the first voltage having the first frequency f1 and a stopping point of time for the supply of the second voltage should be appropriately matched to each other. Also, it is required that the stopping point of time for the supply of the first voltage and the starting point of time for the supply of the second voltage should be appropriately matched to each other.

On the contrary, when a voltage is supplied according to a frequency variation shown in FIG. 8, the first voltage having the relatively low first frequency f1 is supplied during the deposition time. Also the start and stop of the supply of the second voltage having the second frequency f2 are alternately performed. As a result, unlike FIG. 5, it is possible to reduce the burden of matching the start and stop of the supply of the first voltage to those of the second voltage.

In the embodiment of the present invention, the first frequency f1 can be equal to or more than 13.56 MHz. The second frequency f2 is higher than the first frequency f1.

In the embodiment of the present invention, a thickness of the first sub-layer 233A made of amorphous silicon can be equal to or more than 10 nm. A sum of the thickness of the first sub-layer 233A and the thickness of the second sub-layer 233B, which are formed during one cycle P, can be equal to or less than 50 nm. It is more desirable that the sum is less than 30 nm.

Here, during equal to or more than three cycles P, the thickness of the light absorbing layer 233 including the first and the second sub-layers 233A and 233B can be equal to or more than 150 nm and equal to or less than 350 nm.

For example, if a sum of the thickness of the first sub-layer 233A and the thickness of the second sub-layer 233B, which are formed during one cycle P, is 50 nm, a light absorbing layer 233 can be formed, which has a thickness of 150 nm in three cycles and includes three first sub-layers 233A and three second sub-layers 233B.

When a light absorbing layer 233 having a thickness equal to or more than 150 nm and equal to or less than 350 nm is formed during a time period less than three cycles, the thickness of the first sub-layer 233A made of amorphous silicon layers is excessively increased. If a thickness of the first sub-layer 233A, stabilization efficiency is degraded since recombinations of carriers are increased due to higher photocreation of dangling bonds in the amorphous silicon matrix in accordance with the light incidence thereto.

Here, the thicknesses of the first and second sub-layers 233A and 233B may not be entirely uniform due to the uncertainty of the process conditions and parameters. An uniformity degree of each thickness of the first and second sub-layers 233A and 233B may be in a range that the deviation from the mean value of the each thickness is equal to or less than 10%. By maintaining the degree of thickness uniformity of each of the first and second sub-layers 233A and 233B in the above mentioned range, it is possible to prevent the properties of the light abosorbing layer 233 from being deteriorated due to the recombination increase in the first sub-layer 233A and the columnar growth of crystal grains in the second sub-layer 233B.

A diameter of a crystalline silicon grain in the second sub-layer 233B can be equal to or more than 3 nm and equal to or less than 10 nm. It is difficult to form a crystalline silicon grain having a diameter less than 3 nm and a degradation rate reduction effect of a solar cell is reduced. If the crystalline silicon grain has a diameter greater than 10 nm, the volume of grain boundary surrounding the crystalline silicon grain is excessively increased. Therefore, carrier recombination also increases and so the efficiency may decrease.

When such a light absorbing layer is included in a top cell of a single junction photovoltaic device or a multiple junction photovoltaic device, an optical band gap of the light absorbing layer can be equal to or more than 1.85 eV and equal to or less than 2.0 eV. The top cell corresponds to a photoelectric transformation layer on which light is first incident among photoelectric transformation layers included in the multiple junction photovoltaic device.

To form the crystalline silicon grain generates a quantum effect caused by quantum dots. The light absorbing layer 233 according to the embodiment of the present invention has hereby a large optical band gap which is equal to or more than 1.85 eV and equal to or less than 2.0 eV. If the optical band gap is equal to or more than 1.85 eV, it is possible to for the light absorbing layer to absorb much light with a short wavelength having a high energy density. If the optical band gap is greater than 2.0 eV, the light absorbing layer 233 including the plurality of sub-layers 233A and 233B is difficult to form and absorption of light is reduced. Therefore, the efficiency can be reduced by reduction of a short-circuit current.

An average hydrogen content of the light absorbing layer 233 including a plurality of the sub-layers 233A and 233B can be equal to or more than 15 atomic % and equal to or less than 25 atomic %. If the average hydrogen content of the light absorbing layer 233 is less than 15 atomic %, the size and density of the quantum dot are reduced, and then the optical band gap of the light absorbing layer 233 can be reduced and the degradation rate of the light absorbing layer 233 can be increased. If the average hydrogen content of the light absorbing layer 233 is greater than 25 atomic %, the diameter of the crystalline silicon grain is excessively increased so that a volume of unstable amorphous silicon is also increased. Accordingly, the degradation rate can be increased.

In forming the light absorbing layer 233, source gases, for example, oxygen, carbon or germanium as well as hydrogen and silane can be flown to the chamber 310. Here, a flow rate of the source gas such as oxygen, carbon or germanium can be maintained constant during the deposition time. As the flow rate of the source gas such as oxygen, carbon or germanium can be maintained constant, a quality of film of the first sub-layer 233A and a film characteristic of the second sub-layer 233B can be maintained to an appropriate and constant level.

When oxygen is flown to the chamber 310, the first sub-layer 233A and the second sub-layer 233B include hydrogenated amorphous silicon oxide (i-a-SiO:H). The crystalline silicon grain of the second sub-layer 233B is surrounded by the hydrogenated amorphous silicon oxide. When the light absorbing layer 233 including a plurality of the sub-layers 233A and 233B is formed by a flow of oxygen, the thickness of the light absorbing layer 233 is equal to or more than 150 nm and is equal to or less than 300 nm. An average oxygen content of the light absorbing layer 233 can be equal to or more than 0 atomic % and is equal to or less than 3 atomic %. An optical band gap of the light absorbing layer 233 can be equal to or more than 1.85 eV and is equal to or less than 2.1 eV.

When carbon is flown to the chamber 310, the first sub-layer 233A and the second sub-layer 233B include hydrogenated amorphous silicon carbide (i-a-SiC:H). The crystalline silicon grain of the second sub-layer 233B is surrounded by the hydrogenated amorphous silicon carbide. When the light absorbing layer 233 including a plurality of the sub-layers 233A and 233B is formed by a flow of carbon, the thickness of the light absorbing layer 233 is equal to or more than 150 nm and is equal to or less than 300 nm. An average carbon content of the light absorbing layer 233 can be equal to or more than 0 atomic % and is equal to or less than 3 atomic %. An optical band gap of the light absorbing layer 233 can be equal to or more than 1.85 eV and is equal to or less than 2.1 eV.

If the optical band gap of the light absorbing layer 233 formed by a flow of hydrogen or carbon is equal to or more than 1.85 eV, the light absorbing layer 233 can absorb a lot of light with a short wavelength having a high energy density. If the optical band gap of the light absorbing layer 233 is greater than 2.1 eV, the light absorbing layer 233 including the plurality of sub-layers 233A and 233B is difficult to form and absorption of light is reduced. Therefore, the efficiency can be reduced by reduction of a short-circuit current.

When an average oxygen content or an average carbon content of the light absorbing layer 233 formed by a flow of oxygen or carbon is greater than 3 atomic %, the optical band gap of the light absorbing layer 233 is abruptly increased and a dangling bond density is suddenly increased. As a result, the short-circuit current and a fill factor (FF) are reduced, so that the efficiency is degraded.

As such, the light absorbing layer 233 formed by a flow of oxygen or carbon can be included in the top cell of a multiple junction photovoltaic device.

When germanium is flown to the chamber 310, the first and the second sub-layers 233A and 233B include hydrogenated amorphous silicon germanium (i-a-SiGe:H). The crystalline silicon grain of the second sub-layer 233B is surrounded by the hydrogenated amorphous silicon germanium. When the light absorbing layer 233 including a plurality of the sub-layers 233A and 233B is formed by a flow of germanium, the thickness of the light absorbing layer 233 is equal to or more than 300 nm and is equal to or less than 1000 nm. An average geranium content of the light absorbing layer 233 can be equal to or more than 0 atomic % and is equal to or less than 20 atomic %. An optical band gap of the light absorbing layer 233 can be equal to or more than 1.3 eV and is equal to or less than 1.7 eV. If the optical band gap of the light absorbing layer 233 formed by a flow of germanium is equal to or more than 1.3 eV and is equal to or less than 1.7 eV, the deposition rate of the light absorbing layer 233 is prevented from being rapidly reduced and the dangling bond density and a recombination are reduced. Therefore, the efficiency is prevented from being degraded.

If an average germanium content of the light absorbing layer 233 formed by a flow of germanium is greater than 20 atomic %, the deposition rate of the light absorbing layer 233 is abruptly reduced and a recombination is increased by the increase of the dangling bond density. Consequently, the short-circuit current, the fill factor (FF) and the efficiency are reduced.

Meanwhile, when the light absorbing layer 233 is formed by a flow of oxygen, carbon or germanium, the average hydrogen content of the light absorbing layer 233 can be equal to or more than 15 atomic % and equal to or less than 25 atomic %.

Thus, the light absorbing layer 233 formed by a flow of germanium can be included in either a bottom cell of a double junction photovoltaic device including two photoelectric transformation layers 230 or a middle cell of a triple junction photovoltaic device including three photoelectric transformation layers 230. In other words, the light absorbing layer 233 formed by a flow of germanium can be included in a photoelectric transformation layer adjacent to a photoelectric transformation layer on which light is first incident.

That is to say, since the optical band gap of the light absorbing layer 233 formed by a flow of germanium is equal to or more than 1.3 eV and is equal to or less than 1.7 eV, and thus, is less than an optical band gap, which is equal to or more than 1.85 eV and equal to or less than 2.0 eV, of the light absorbing layer used in the top cell. Accordingly, the light absorbing layer 233 formed by a flow of germanium can be used in either the bottom cell of the double junction photovoltaic device or the middle cell of the triple junction photovoltaic device including three photoelectric transformation layers 230.

The average germanium content is equal to or more than 0 atomic % and equal to or less than 20 atomic %. Therefore, since there is a possibility that the average germanium content may be greater than the average oxygen content or the average carbon content, the deposition rate can be reduced. Accordingly, the first frequency f1 can be equal to or more than 27.12 MHz, greater than 13.56 MHz. The increased first frequency f1 improves a deposition rate and causes the quantum dots to be easily formed.

The foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures. Moreover, unless the term “means” is explicitly recited in a limitation of the claims, such limitation is not intended to be interpreted under 35 USC 112(6).

What is claimed is:

1. A photovoltaic device comprising:
a substrate;
a first electrode disposed on the substrate;
a photoelectric transformation layer disposed on the first electrode, the photoelectric transformation layer comprising a light absorbing layer which comprises at least one pair of an intrinsic first sub-layer and an intrinsic second sub-layer, each of which comprises hydrogenated amorphous silicon based material and hydrogenated proto-crystalline silicon based material having a crystalline silicon grain; and
a second electrode disposed on the photoelectric transformation layer.

2. The photovoltaic device of claim 1, wherein the hydrogenated amorphous silicon based material is hydrogenated amorphous silicon oxide (a-SiO:H) or hydrogenated amorphous silicon carbide (a-SiC:H), and the crystalline silicon grain is surrounded by the hydrogenated amorphous silicon oxide (a-SiO:H) or the hydrogenated amorphous silicon carbide (a-SiC:H).

3. The photovoltaic device of claim 1, wherein the hydrogenated amorphous silicon based material is hydrogenated amorphous silicon germanium (a-SiGe:H), and the crystalline silicon grain is surrounded by the hydrogenated amorphous silicon germanium (a-SiGe:H).

4. The photovoltaic device of claim 2, wherein a diameter of the crystalline silicon grain is equal to or more than 3 nm and equal to or less than 10 nm.

5. The photovoltaic device of claim 2, wherein an average hydrogen content of the light absorbing layer is equal to or more than 15 atomic % and equal to or less than 25 atomic %.

6. The photovoltaic device of claim 2, wherein a thickness of the light absorbing layer is equal to or more than 150 nm and equal to or less than 300 nm.

7. The photovoltaic device of claim 3, wherein a thickness of the light absorbing layer is equal to or more than 300 nm and equal to or less than 1000 nm.

8. The photovoltaic device of claim 2, wherein a thickness of the list sub-layer is equal to or more than 10 nm.

9. The photovoltaic device of claim 2, wherein a sum of thicknesses of the first sub-layer and the second sub-layer in each of the pair is equal to or less than 50 nm.

10. The photovoltaic device of claim 2, wherein an optical band gap of the light absorbing layer is equal to or more than 1.85 eV and equal to or less than 2.1 eV.

11. The photovoltaic device of claim 3, wherein an optical band gap of the light absorbing layer is equal to or more than 1.3 eV and equal to or less than 1.7 eV.

12. The photovoltaic device of claim 2, wherein an average oxygen content or an average carbon content of the light absorbing layer is equal to or more than 0 atomic % and equal to or less than 3 atomic %.

13. The photovoltaic device of claim 3, wherein an average germanium content of the light absorbing layer is equal to or more than 0 atomic % and equal to or less than 20 atomic %.

14. The photovoltaic device of claim 2, wherein the photovoltaic device comprises a plurality of photoelectric transformation layers, and the light absorbing layer is included in the photoelectric transformation layer on which light is first incident among the plurality of photoelectric transformation layers.

15. The photovoltaic device of claim 3, wherein the photovoltaic device comprises a plurality of photoelectric transformation layers, and the light absorbing layer is included in the photoelectric transformation layer adjacent to a photoelectric transformation layer on which light is first incident among the plurality of photoelectric transformation layers.

16. The photovoltaic device of claim 2, wherein an uniformity degree of each thickness of the first sub-layer and the second sub-layer is in a range that a deviation from the mean value of the each thickness is equal to or less than 10%.

17. The photovoltaic device claim 3, wherein a diameter of the crystalline silicon grain is equal to or more than 3 nm and equal to or less than 10 nm.

18. The photovoltaic device of claim 3, wherein an average hydrogen content of the light absorbing layer is equal to or more than 15 atomic % and equal to or less than 25 atomic %.

19. The photovoltaic device of claim 3, wherein a thickness of the first sub-layer is equal to or more than 10 nm.

20. The photovoltaic device of claim 3, wherein a sum of thicknesses of the first sub-layer and the second sub-layer in each of the pair is equal to or less than 50 nm.

21. The photovoltaic device of claim 3, wherein an uniformity degree of each thickness of the first sub-layer and the second sub-layer is in a range that a deviation from the mean value of the each thickness is equal to or less than 10%.
